(19) United States
(12) Patent Application Publication
(10) Pub. No.: US 2009/0186745 A1
(43) Pub. Date: Jul. 23, 2009

(54) SOLAR STRUCTURE

(75) Inventor: Jason Lewiston, Oak Park, MI (US)

Correspondence Address: RADER, FISHMAN & GRAUER PLLC, 39533 WOODWARD AVENUE, SUITE 140, BLOOMFIELD HILLS, MI, 48304-0610, US

(73) Assignee: Energy Alpha Corporation

(21) Appl. No.: 12/016,003

(22) Filed: Jan. 17, 2008

(51) Int. Cl. A63B 17/00; H01L 31/048; F03D 9/00

(52) U.S. Cl. 482/2; 136/251; 290/55

(57) ABSTRACT

A solar structure having a support structure and at least one solar panel capable of being supported by the support structure in an orientation to receive sunlight for conversion to electrical power. The support structure includes a roof frame and a plurality of columns capable of supporting the roof frame above the ground.

### TECHNICAL FIELD

The present disclosure relates to renewable power collection structures, and more particularly to modular solar power structures.

### BACKGROUND

Many consumers have considered buying and using solar power to satisfy at least a part of their residential electric power supply needs. Several factors have recently contributed to an increase in this interest.

Consumers are increasingly concerned about the out-of-pocket cost of electric power derived from fossil fuel sources such as coal, oil and natural gas. These increasing prices are raising the level of awareness and concern about the truly non-renewable nature of these fuels and contributing to a desire to use renewable energy sources such as solar power where practical. Some consumers are additionally concerned about the financial and political implications of the large amounts of money being paid by citizens of stable democracies to less democratic and, in some cases, less stable regimes for such fuels. Others are concerned about the environmental implications of the extraction and consumption of these fossil fuels even with state of the art technology. Headlines describing the potential for harm from global warming continue to raise not only awareness but anxiety and feelings of guilt for many consumers. Still other consumers are concerned about the reliability of the power grid and the power lines supplying their homes.

Fortunately, solar power technology continues to improve significantly, making use of solar power easier and more practical than ever before for home owners. Furthermore, energy legislation and power company initiatives have made it increasingly easy for consumers who chose to generate their own power to connect their residential power generation system to their electric power meter and sell their excess power to their power company, making use of their own solar power generator more economical.

However, many homeowners remain unwilling or uninterested in buying and installing their own solar power generating system. Some homeowners may be reluctant to adopt solar power because they do not like the aesthetics of solar panels, particularly when the panels are mounted on a residential roof. Therefore, the need has arisen for an easy to assemble solar structure that can be pleased in the rear yard of a home and provide power for the home and that encourages the use of solar power.

Meanwhile, there is a growing movement to encourage people, especially children, to spend more time in outdoor recreational activities. Many homeowners are assembling out door activity centers and outdoor activity structures to promote outdoor activities by their family and to provide a space for entertaining visiting families.

In light of the foregoing, a need has arisen for a solar power structure that supports outdoor activities.

### BRIEF SUMMARY

A solar structure including a support structure having a roof frame supported by a plurality of columns is described. The solar structure further includes at least one solar panel supported by the support structure in an orientation to receive sunlight and convert it into electrical power.

In accordance with one exemplary assembly, the solar structure includes an activity device supported by the support structure and located below the roof frame. In one version of this exemplary assembly, a roof capable of being suspended from the support structure is provided between the roof frame and the activity device.

In accordance with another exemplary assembly, a plurality of solar panels is provided.

In accordance with another exemplary assembly, the solar panel is pivotably supported by the roof frame to be pivotable to an orientation to better receive sunlight. For example, a solar panel should face South when located in the Northern Hemisphere.

In accordance with yet another exemplary assembly, a power converter capable of being supported by the support structure is provided. The power converter is electrically connected to plurality of solar panels to receive electric power from the plurality of solar panels and convert the power from a first format to a second format.

The present invention will be more fully understood upon reading the following detailed description in conjunction with the accompanying drawings.

### BRIEF DESCRIPTION OF THE DRAWINGS

Embodiments of the disclosure will now be described, by way of example, with reference to the accompanying drawings, wherein:

FIG. 1 a sunward elevational view of an exemplary solar structure;

FIG. 2 is side elevational view of the solar structure of FIG. 1;

FIG. 3 is top plan view of the solar structure of FIG. 1;

FIG. 4 is a partial top plan view of one of the columns of the solar structure of FIGS. 1-3;

FIG. 5 is a perspective view of a bracket connecting the column of FIG. 4 to the roof frame of the solar structure of FIGS. 1-3;

FIG. 6a is an enlarged portion of FIG. 2 showing an elevational view of one solar panel assembly in lowered position for assembly or for use at the equator;

FIG. 6b is an enlarged portion of FIG. 2 showing an elevational view of one solar panel assembly in a raised position for alignment with incoming solar rays;

FIG. 7a is an enlarged portion of FIG. 1 showing an elevational view of one solar panel assembly in a first orientation;

FIG. 7b is an enlarged portion of FIG. 1 showing an elevational view of on solar panel assembly in a second orientation for better alignment with the sun;

FIG. 8 an exemplary schematic of a solar power collection system for the solar structure;

FIG. 9 is sunward elevational view of an exemplary solar structure with traditional jungle gym recreational equipment attached;

FIG. 10 is top plan view of the solar structure with traditional jungle gym recreational equipment attached of FIG. 6 with the roof frame, solar panel assemblies and cloth roof removed;

FIG. 11 is sunward elevational view of an exemplary solar structure with alternative contemporary jungle gym recreational equipment attached;

FIG. 12 is top plan view of the solar structure with alternative jungle gym recreational equipment attached of FIG. 11 with the roof frame, solar panel assemblies and cloth roof removed;

FIG. 13 is a sunward elevational view of an exemplary solar structure with a playhouse attached;

FIG. 14 is a sunward elevational view of an exemplary solar structure with a practice soccer arena and goal attached;

FIG. 15 is top plan view of the solar structure with a practice soccer arena and goal attached of FIG. 6 with the roof frame, solar panel assemblies and cloth roof removed;

FIG. 16 is a side elevational view of an exemplary solar structure with an externally oriented goal attached;

FIG. 17 is a top plan view of an example of a solar structure with a putting green attached with the roof frame, solar panel assemblies and cloth roof removed;

FIG. 18 is a top plan view of an example of a solar structure with a kennel attached with the roof frame, solar panel assemblies and cloth roof removed;

FIG. 19 is top plan view of an exemplary structure with an entertainment and dining systems, the roof frame, solar panel assemblies and cloth roof being removed for illustrative purposes; and

FIGS. 20 and 21 are a top plan views similar to FIG. 19 illustrating alternative entertainment and dining systems.

### DETAILED DESCRIPTION

The present disclosure relates to a solar structure and more particularly a modular solar structure that serves the dual purpose of providing solar power and supporting an outdoor activity.

Exemplary illustrations of a solar structure are described below. In the interest of clarity, not all features of an actual implementation are described in this specification. It will of course be appreciated that in the development of any such actual illustration, numerous implementation-specific decisions must be made to achieve the developers' specific goals, such as compliance with system-related and business-related constraints that will vary from one implementation to another. Moreover, it will be appreciated that such a development effort might be complex and time-consuming, but would nevertheless be a routine undertaking for those of ordinary skill in the art having the benefit of this disclosure.

Referring now to the drawings wherein like numerals indicate like or corresponding parts throughout the several views, exemplary embodiments are illustrated.

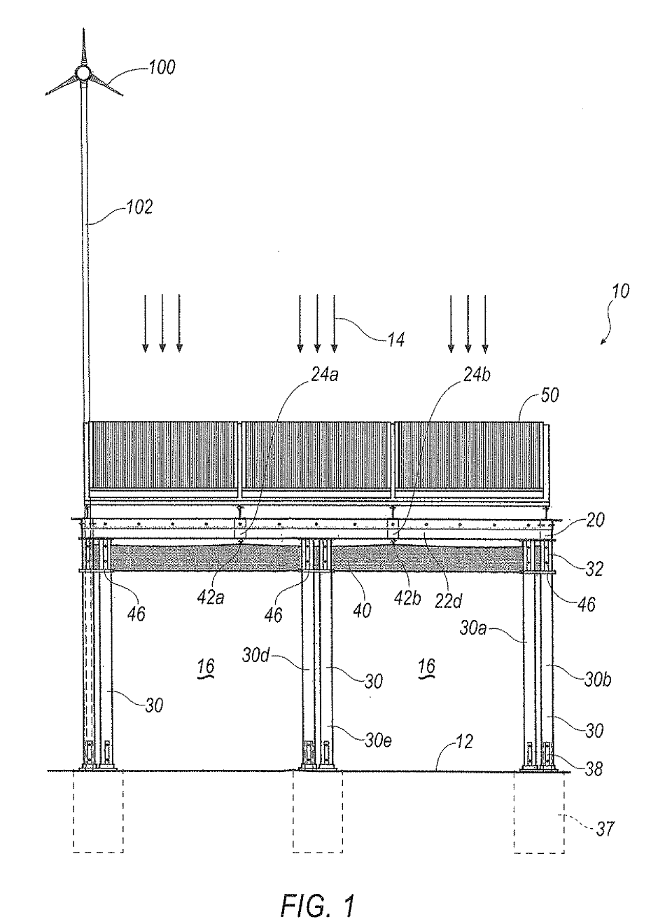

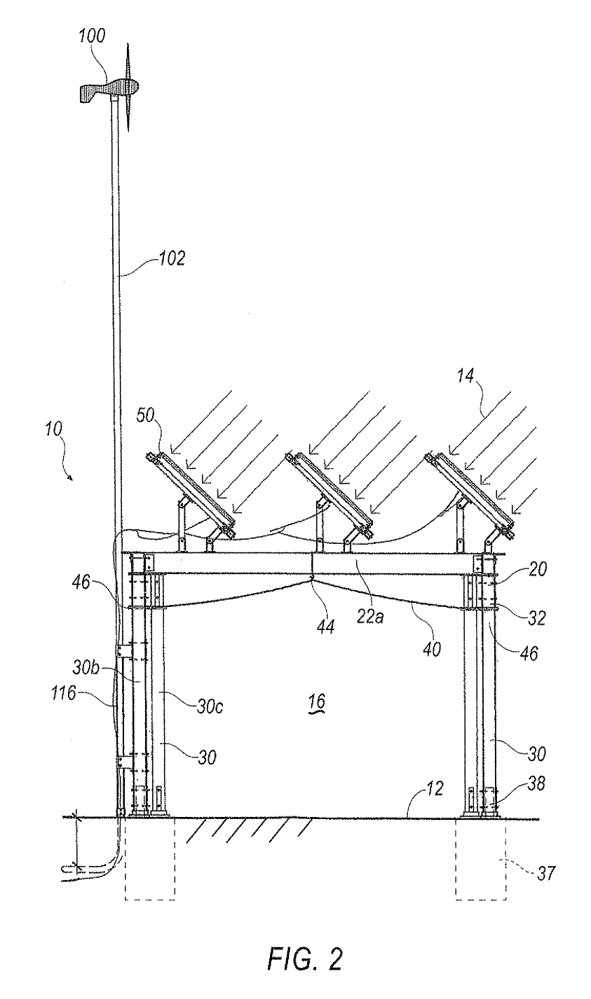

FIGS. 1, 2 and 3 illustrate an exemplary solar structure 10 resting on the ground 12 in an area exposed to incoming solar rays 14. As shown in FIGS. 1 and 2, the solar structure includes a support structure having a roof frame 20 supported by columns 30. The solar structure 10 defines an activity space 16 below the roof frame 20.

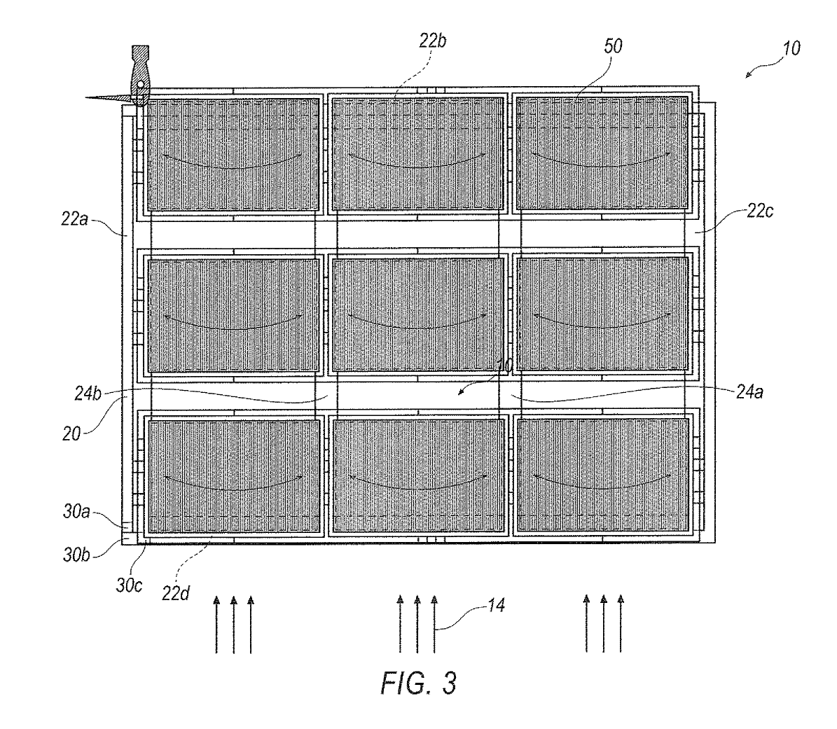

In the example illustrated, and as best shown in FIG. 3, the roof frame may be formed of four side beams 22a-22d and one or more cross beams 24. The beams illustrated are formed of a strong weather resistant material and selected from commercially available materials, such as aluminum or treated parallam pergola beams. The beams are selected and engineered to be capable of supporting the weight of an array of solar panels assemblies 50, described later herein in detail, and to provide mounting points for the solar panel assemblies. The roof frame 20 may be provided to a consumer or builder in preassembled condition or in kit form with appropriate brackets and fasteners (not shown). If provided in kit form, the side beams 22a-22d and the cross beams 24 may be predrilled to facilitate assembly. In the example illustrated, the roof is rectangular and approximately twenty (20) to thirty (30) feet wide or six (6) to nine (9) meters wide by approximately ten (10) to fifteen (15) feet deep or three (3) to four and one-half (4.5) meters deep to define an activity space 16 of approximately between two-hundred (200) and four hundred and fifty (450) square feet or eighteen (18) to forty-two (42) square meters. It will be appreciated that other shapes and sizes, including various regular and irregular polygonal and arcuate shapes may be used depending on architectural preferences, the budget, the building site, and the materials available, the number and sizes of solar collectors desired, and the type of outdoor activity intended to be supported by the solar structure 10.

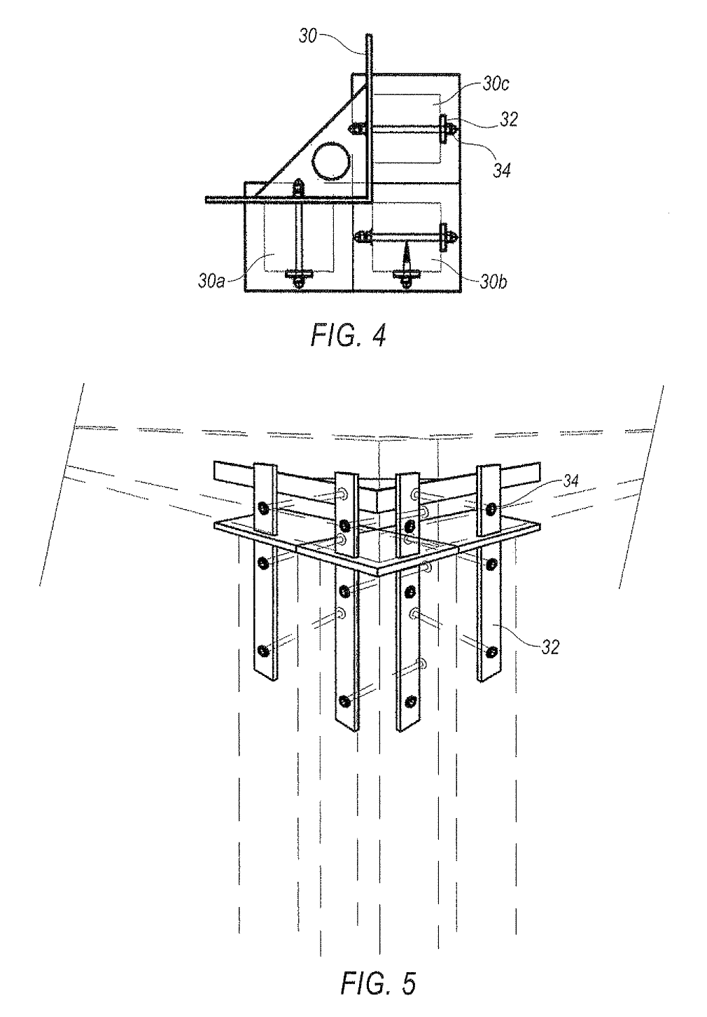

The roof frame is supported by columns 30 as shown in FIGS. 1 and 2. In the example illustrated, there are six columns of 10 foot to 15 foot height, one column at each corner of the roof frame 20 and two additional columns supporting intermediate portions of opposing side beams 22b and 22d. The columns 30 are formed of strong weather resistant material and selected from commercially available materials. In the example illustrated, the corner columns 30 each comprise three aluminum or treated parallam pergola posts 30a, 30b and 30c, as best shown in FIGS. 3 and 4. Similarly, each of the intermediate columns comprise two aluminum or treated parallam pergola posts 30d and 30e, as shown in FIG. 1. The number, height and placement of the columns 30 may vary depending on the size, weight and shape of the support structure, the materials available, and the activities which the support structure supports. The columns 30 are selected and engineered to be capable of supporting the combined weight of the roof frame 20 and the array of solar panels assemblies 50, described later herein. The columns 30 and may be predrilled to facilitate on site assembly. The columns 30 may also be predrilled to provide mounting points for activity devices, to be described later herein.

Each of the columns 30 is supported by an anchor post 37, which is buried in the ground 12 to provide a footing for the column. The anchor posts 37 are selected for compliance with local code and engineered to exceed the minimum depth and anchorage requirements to support the solar structure 10. A bracket 38 and associated fasteners, not shown, secures the lower end of each column 30 to its associated anchor post 37. While the columns 30 and the anchor posts 36 are illustrated as being designed for level ground installation, it is recognized that for some installations the columns 30 and/or anchor posts 37 may be engineered to take variations in terrain into account.

As best shown in FIGS. 4 and 5, brackets 32 and appropriate fasteners 34 are provided at the top of each of the columns 30 for connecting the roof frame 20 to the columns. The columns 30 and the roof frame 20 may be predrilled to facilitate the installation of the brackets 32 and fasteners 34.

For some installations, (not shown) such as in an installation remote from the equator, it may be desirable to tilt the roof frame 20 in the sunward direction to obtain better access to the sun. For such installations, it may be desirable to have shorter columns 30 on the sunward side of the solar structure 10. For such installations, the roof frame 20, the columns 30, and the brackets 36 may be engineered to take the loading inherent in a tilted structure into account.

It will be further appreciated that numerous brackets, such as brackets 32 and 38, and associated fasteners may be used to assemble the solar structure 10, including brackets and fasteners to assemble the roof frame 20, to mount the roof frame 20 to the columns 30, to mount 30 the columns to the anchor posts 37, and to mount activity devices 200 to the support structure. These components should be selected for cost, strength and durability. For example, the brackets may typically be aluminum or stainless steel and the fasteners may typically be stainless steel.

As shown in FIGS. 1 and 2, a roof such as a tarp 40 may be suspended from the solar structure 10. The tarp may be formed of a suitable material for outdoor use such as canvas or plastic. The tarp 40 may be secured to the roof frame 20 and/or the columns 30 at various locations. In the example illustrated, the tarp 40 may be secured along a center line by ties 42a and 42b respectively to cross beams 24a and 24b, as shown in FIG. 1. The tarp 40 may be further secured by tie 44 to side beam 22a as shown in FIG. 2, as well as by a similar tie, not shown, to opposing side beam 22c. The tarp 40 is also shown secured by ties 46 along its front and back edges to form an arcuate sloped effect extending in either direction from its center line defined by ties 42a, 42b and 44 as is traditional for tarp roofing. The tarp 40 provides shading and an aesthetic and physical barrier between the solar panel assemblies 50 and the activity space 16 defined between the columns 30 and below the roof frame 20.

As shown in FIGS. 1, 2 and 3, an array of solar panel assemblies 50 are supported by the roof frame 20. In the example illustrated, a three by three array of nine solar panel assemblies are provided. The number, shape and size of the solar panel assemblies and the manner in which they are arrayed on the roof assembly may differ from that illustrated depending on the size and shape of the arrays available, the size and shape of the roof frame 20, the power needs of the owner, and the angle of the incoming rays of sunlight 14. Additional support or mounting surfaces, not shown, may be provided on the roof frame 20 where and as needed to provide support or mounting points for the solar panel assemblies 50. As mentioned above, for extreme geographic locations, the more sunward rows of solar panel assemblies 50 may cast a shadow on the more rearward rows, so it may be advantageous to tilt the roof frame 20 to provide better access of the array of solar collectors to the sunlight. Alternatively, the rear rows of solar panel assemblies 50 may be raised by an appropriate support, such as an additional beam, not shown, relative to the sunward row of solar panel assemblies.

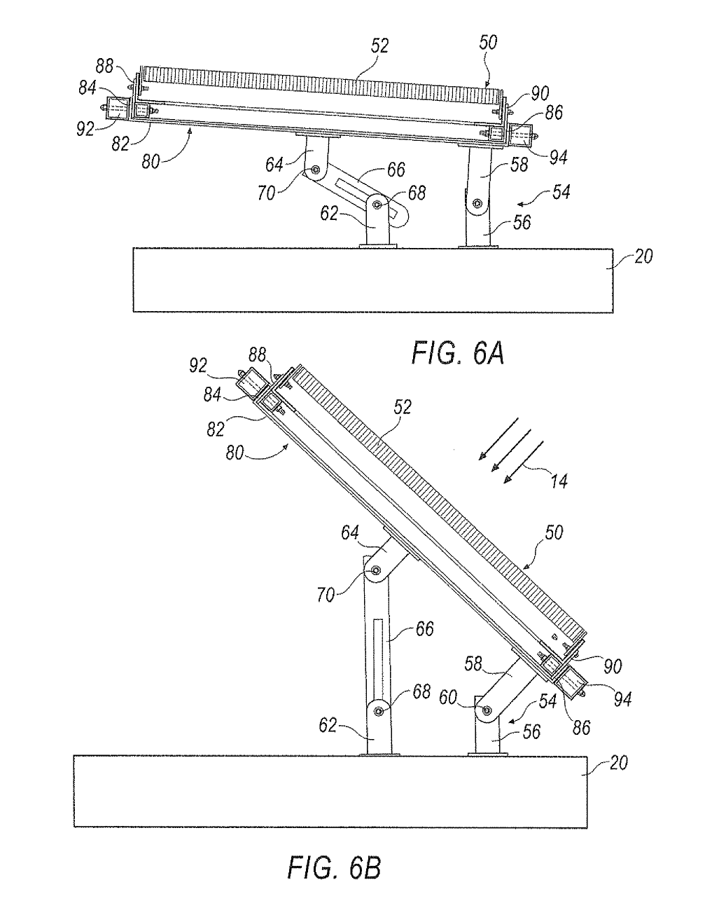

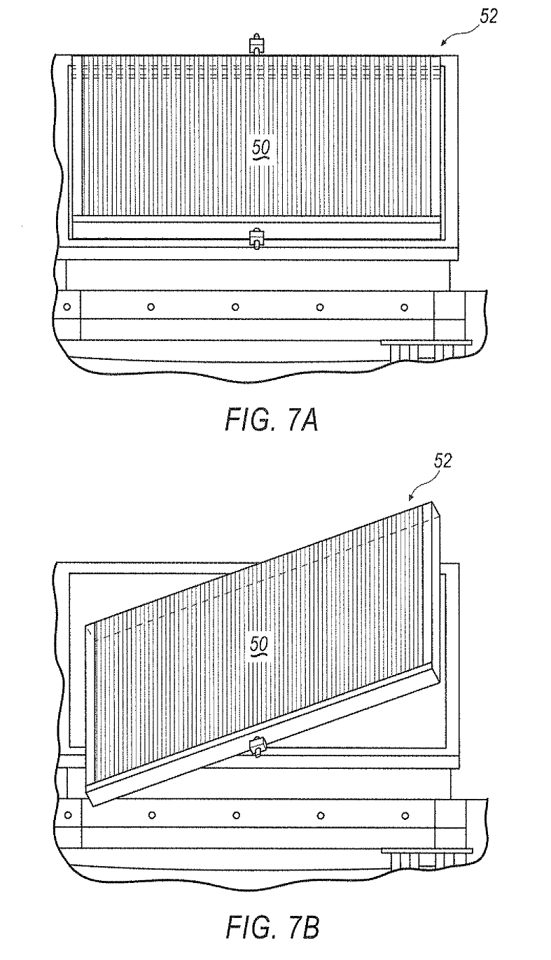

Additional details of an exemplary one of the solar panel assemblies 50 are shown in FIGS. 6a, 6b, 7a and 7b. As shown in FIGS. 6a and 6b, the solar collectors 52 may be tilted upwardly in the sunward direction between a lowered position shown in FIG. 6a and a raised position shown in FIG. 6b. As shown in FIGS. 7a and 7b, the solar collectors 52 may also be tilting from side to side, for example, between a first position aligned with the roof frame 20 shown in FIG. 7a and a second position tilted relative to the roof frame as shown in FIG. 7b. The manner in which the illustrated exemplary structure permits tilting of the solar panel assemblies 50 in these two directions is described immediately below.

Referring to FIGS. 6a and 6b, each solar panel assembly 50 includes a solar collector 52 supported by an articulated assembly 54 that supports the solar collector in a position spaced above the roof frame 20 to permit airflow below the solar collector 52. The articulated assembly 54 includes a sunward support having a first bracket 56 mounted directly or indirectly to the roof frame 20 and having an arm extending upwardly from the roof frame. A second bracket 58 is mounted to the underside of the solar collector 52 and has an arm extending downwardly. The ends of the arms of the brackets 56 and 58 are connected by a pin 60 to permit a pivoting motion therebetween. The articulated assembly 54 also includes a rearward support having a first bracket 62 mounted directly or indirectly to the roof frame 20 with an arm extending upwardly from the roof frame, and a second bracket 64 mounted to the underside of the solar collector 52 with an arm extending downwardly, However, the rearward support further includes an intermediate member 66 fastened at one end by a pin 68 to the first bracket 62 and at the other end by a pin 70 to the second bracket 64. The pin 68 rides in a slot in the intermediate member 66 to permit the solar collector 52 to be pivoted about the pin 60. At least pin 68 may be a locking pin that permits a user to selectively adjust the solar collector 52 to a desired angle to maximize the collection of incoming solar rays 14 for the geographic location of the solar structure 10 and the season and then lock the articulated assembly 54 into the desired position. In other cases, there may not be any slot such that a single angle is selected.

In addition to being pivotable up and down relative to the roof frame 20 as described above, each solar collector 52 may be pivotable from side to side and shown in FIGS. 7a and 7b to further improve alignment of the solar collector 52 with the incoming solar rays 14 (FIGS. 2, 3 and 6b). For the illustrated solar panel assembly 52, this is accomplished by interposing a pivotal mounting system 80, as shown in FIGS. 6a and 6b, between the solar collector 50 and the articulated assembly 54 described above. The pivotal mounting system 80 includes a support frame 82 mounted to and supported by the brackets 58 and 64 of the articulated assembly 54. The support frame includes upwardly oriented flanges 84 and 86 that abut downwardly oriented flanges 88 and 90 depending from the solar collector 52. A first locking thumbwheel assembly 92 passes through and joins the flanges 84 and 88 and a second locking thumbwheel assembly 94, passes through and joins flanges 86 and 90. The locking thumbwheel assemblies 92 and 94 are axially aligned and thereby cooperate to pivotably connect the solar collector 52 to the articulated assembly 54.

The articulated assembly 54 and the pivotal mounting system 80 described above are easy to assemble, low in cost, and light weight. However, it is exemplary of a wide variety of support structures that may be used to raise, lower and tilt the solar collector 52 to provide the desired angle. Other adjustable support structures, not illustrated, may be advantageously used, including linkages that simultaneously raise, lower and/or tilt multiple solar collectors.

Referring again to FIGS. 1 and 2, the solar structure 10 may support additional sources of alternative power. For example, one or more wind turbines 100 may be supported on a mast 102 secured to one of the columns 30. As will be described later, alternative power may alternatively or additionally be supplied from an activity associated with the activity space 16.

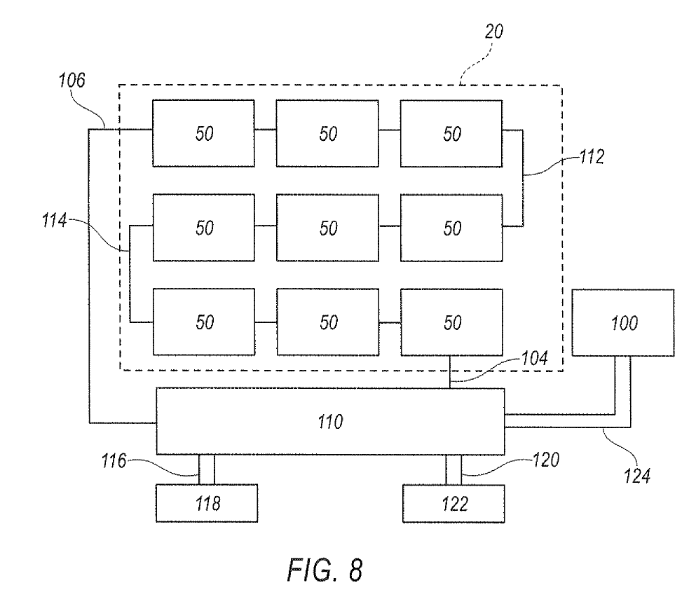

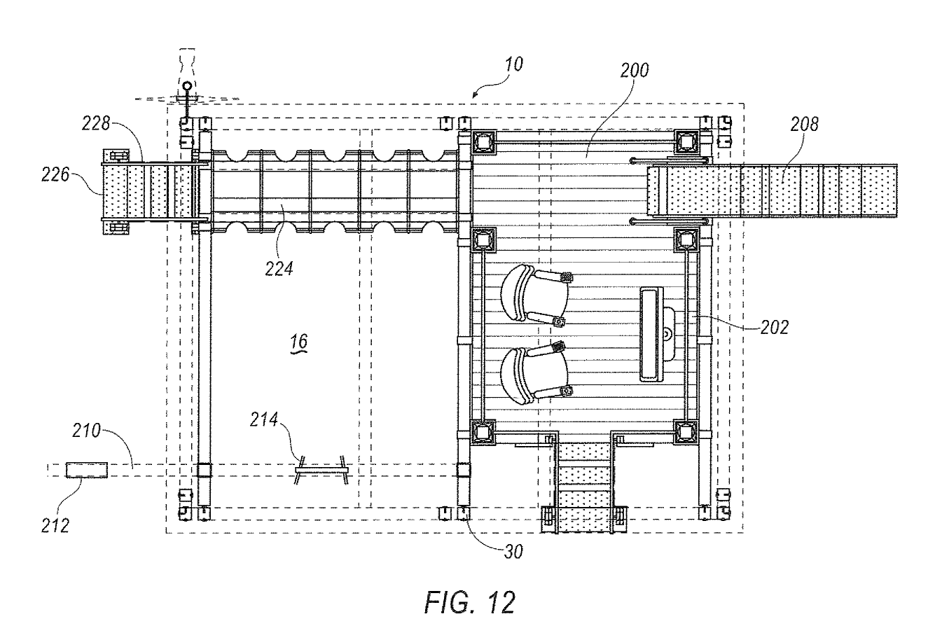

As shown schematically in FIG. 8, the power generated by the solar collectors 52 is delivered by power lines 104 and 106 to an electric power converter 110 which may be supported on the roof frame 20. While the solar collectors 52 are shown in FIG. 12 connected in series to the electric power converter, for example by power lines 112 and 114, this is merely for convenience of illustration. The specific manner in which the solar connectors are connected to the electric power converter 110 will depend on the design of the solar collectors 52 and the electric power converter as well as on the number of solar collectors being used. The electric power converter 110 converts the raw electrical signal received from the solar collectors 52 into a suitable power format for further distribution or use, such as alternating current or direct current. The output of the electric power converter 110 may be delivered by a cable 116 extending down along one of the columns 30 (FIG. 2) to the ground 12 and then underground to a device 118 which may be a suitable power consuming device or to an electric power meter adapted to accept power for retransmission to the power grid. The output of the electric power converter 110 may additionally or alternatively be delivered by a cable 120 to a power consuming device 122 located at the solar structure, such as a light or sound system or a power outlet, not shown. If an additional source of renewable power is provided at the solar structure 10, such as the wind turbine 100, the output of the additional power source may be directed by a power line 124 to the electric power converter 110 for aggregation with the power from the solar collectors 52 and conversion into a more useable power format.

Alternatively, where appropriate, at least some of the electrical power lines 104, 106, 112 or 114 may be wireless connections.

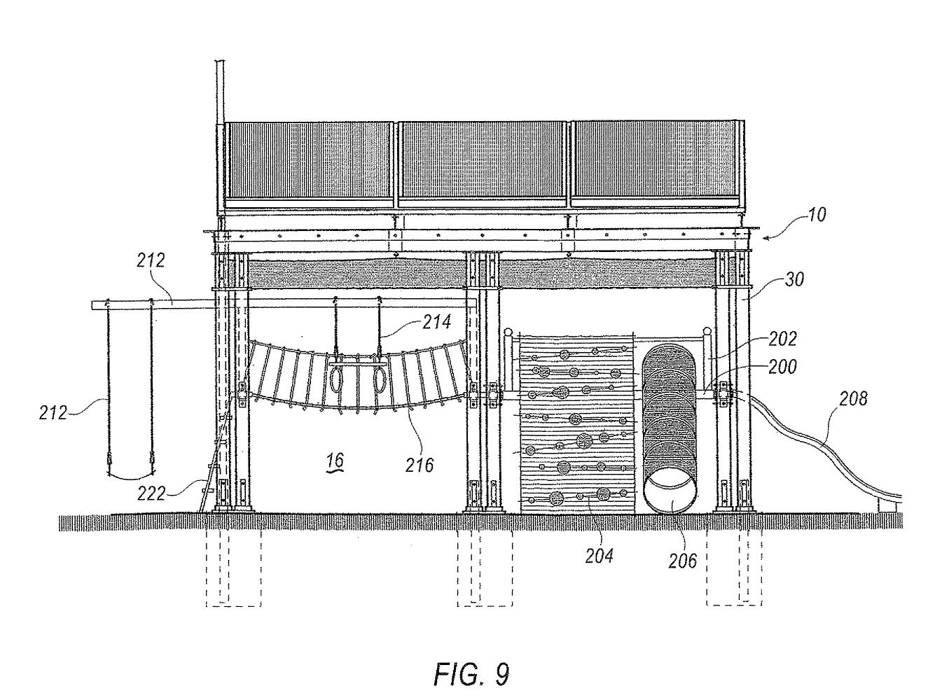

As shown generally in FIGS. 9-21, the solar structure 10 is intended to provide the dual function of providing renewable power and providing support for an outdoor activity with in the activity space 16. In particular, this is accomplished by providing one or more activity devices which may be supported by or mounted to roof frame 20 and or the columns 30 of the support structure.

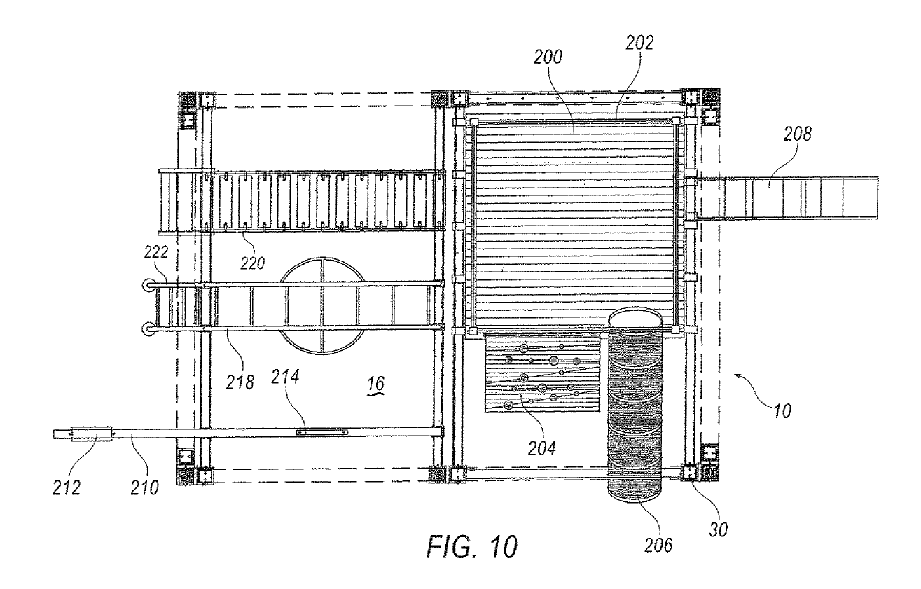

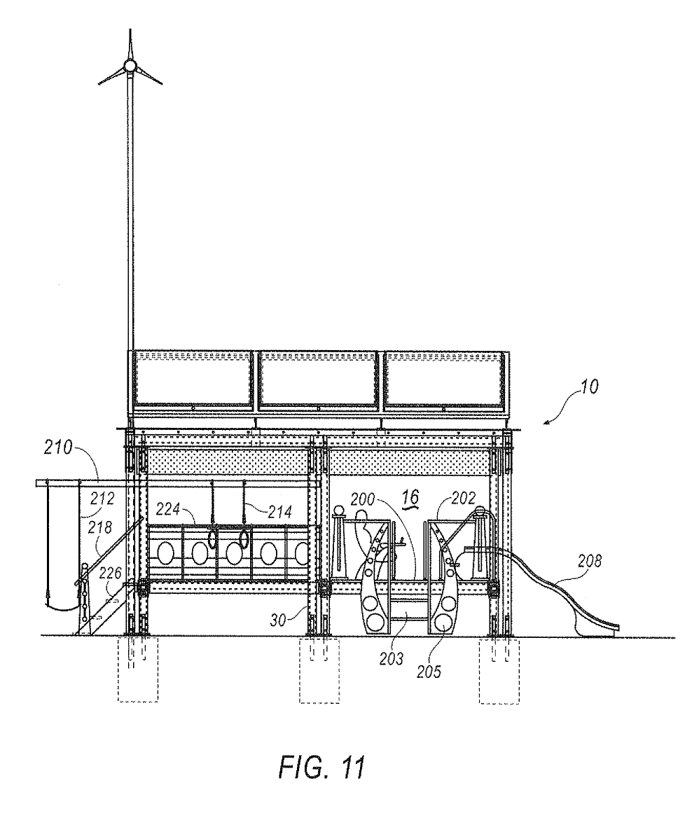

As shown in FIGS. 9-12, several recreational devices may be provided to create alternative jungle gyms, such as the traditional rustic jungle gym shown in FIGS. 9 and 10 and the contemporary jungle gym shown in FIGS. 11 and 12.

A platform 200 having a railing 202 may be mounted to four of the columns 30. A climbing device, such as a climbing wall 204 and a tube 206 shown in FIGS. 9 and 10 or a ladder 203 with a railing 205, shown in FIGS. 11 and 12, may provide access to the platform 200. A slide 208 may provide recreational egress from the platform 200. A pole 210 mounted to two columns 30 may be used for suspending a swing 212 or hanging ropes 214. Recreational bridging devices, such as a rope ladder 216 (FIG. 9), a tubular ladder 218, (FIG. 10), a rope and wood ladder 220 (FIG. 10) or a tubular tunnel 224 (FIGS. 11 and 12), may be mounted to the solar structure 10 across portions of the activity space 16. A climbing device such as a ladder 222 (FIGS. 9 and 10) or a stairway 226 with a railing 228 (FIGS. 11 and 12) may provide access to the recreational bridging device.

It will be appreciated that further variations from the above configurations may be made depending on the size of the activity space 16 and the age of the user. The jungle gym may be further varied to provide an adult exercise facility. Alternatively, the jungle gym may be designed and proportioned to provide an agility training facility for a dog or other domestic animal.

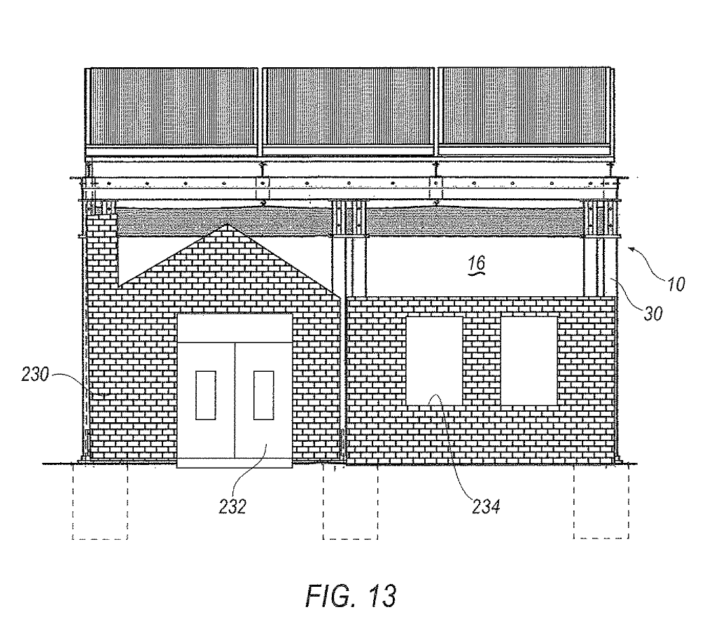

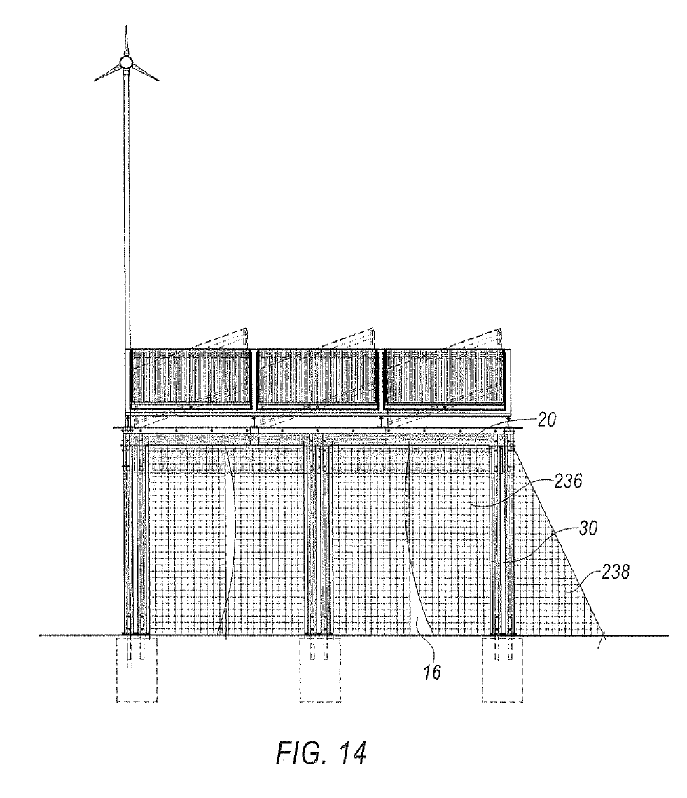

Alternatively, the activity space 16 may be used as a clubhouse as shown in FIG. 13 by attaching one or more decorative panels 230 to the columns 30 that are ornamented to suggest a building such as a home. As shown in the drawing, the panels could have functioning or ornamental doors 232 and windows 234 as well as features suggesting a sloped roof and a chimney. A small number of decorative panels 230 may be used to create a facade for recreational activities. Alternatively, decorative panels 230 may be used on all sides of the solar structure 10 to significantly enclose the activity space 16.

The activity space 16 may be used as practice soccer arena by draping netting 236 from the roof frame 20. The netting 236 may also be secured to the columns 30. A portion of the netting 236 on at least one side of the solar structure 10 may be extended outwardly from the activity space 16 and anchored to the ground 12 to define a goal 238.

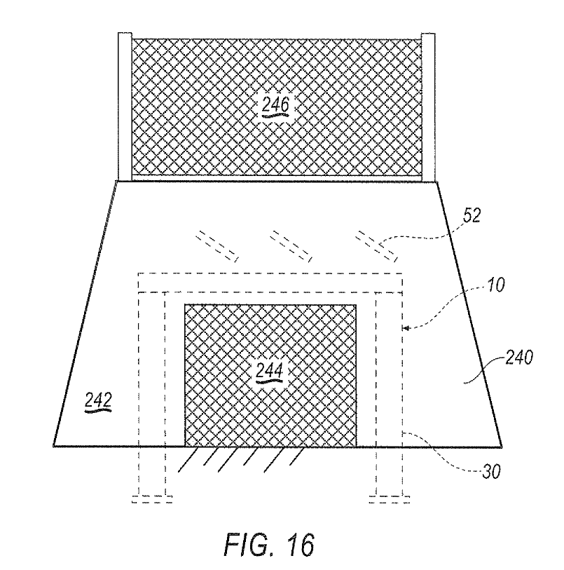

Alternatively, as shown schematically in FIG. 16, the support structure of the solar structure 10 may be used to support a practice goal system 240 for soccer practice in the filed adjacent to the solar structure 10. The practice goal system 240 may also be used for other games such as hockey or field hockey. In the example shown, the goal system includes a resilient wall 242 supported by two columns 30 and having a netted opening 244 extendable into the activity space 16 to define a goal. If needed, the goal system could include additional netting 246 above the goal to deflect balls away from the vicinity of the solar collectors 52.

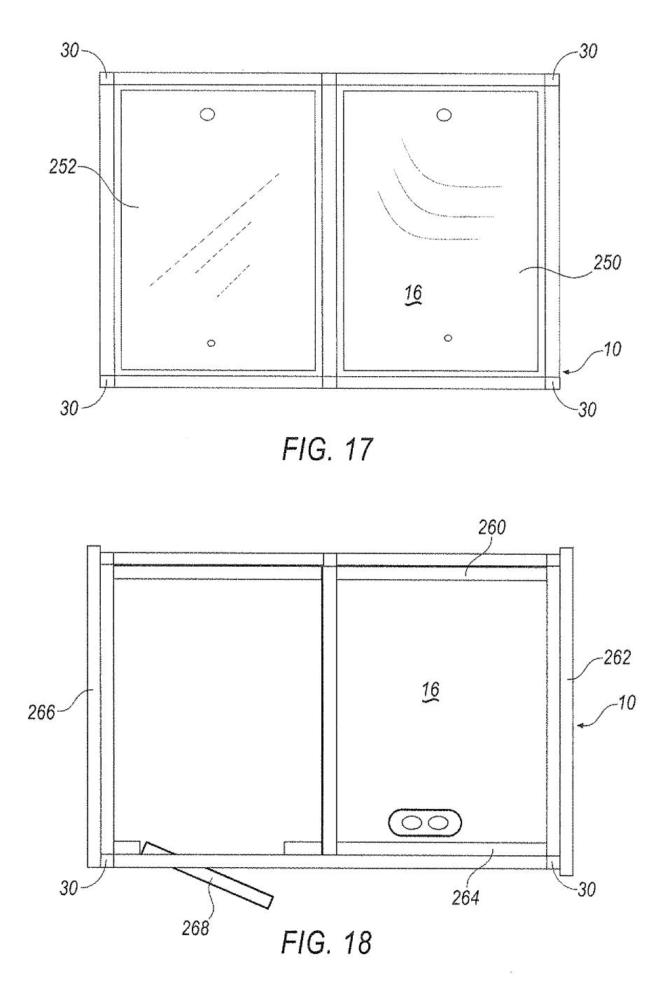

As shown in FIG. 17, the activity device may alternatively be one or more putting greens 250 and 252 secured to columns 30 within the activity space 16.

While the solar structure 10 described with reference to FIGS. 9-17 is well-suited for physically active recreational applications, it can also be used to support a wide variety of additional outdoor activities.

As shown in FIG. 18, the activity device may be four or more removable interlocking fence units 260, 262, 264 and 264 supported by the columns 30 that cooperate to create a pet kennel. At least one of the fence units is provided with a gate 266 for access to the activity space 16.

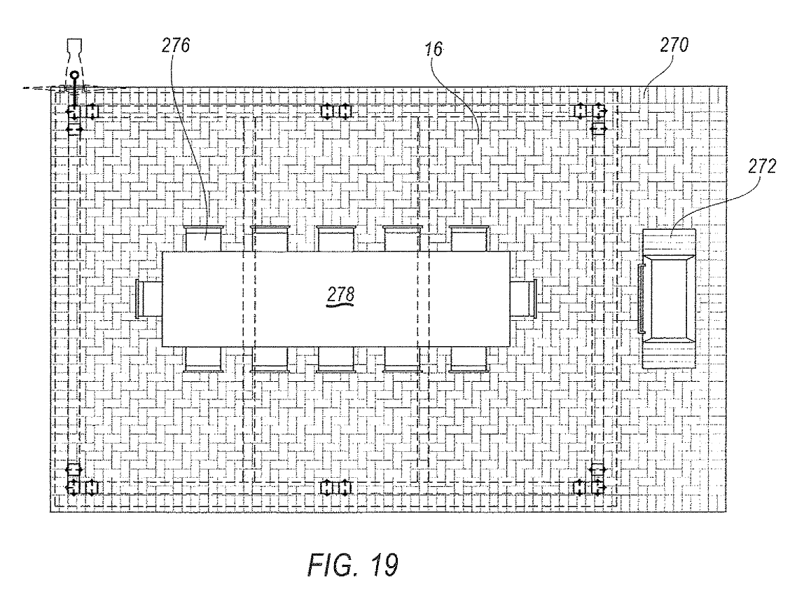

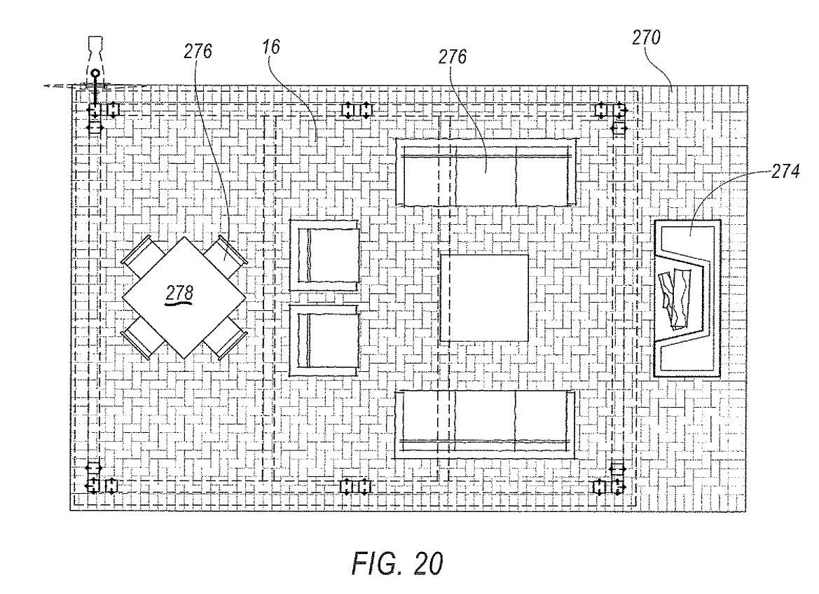

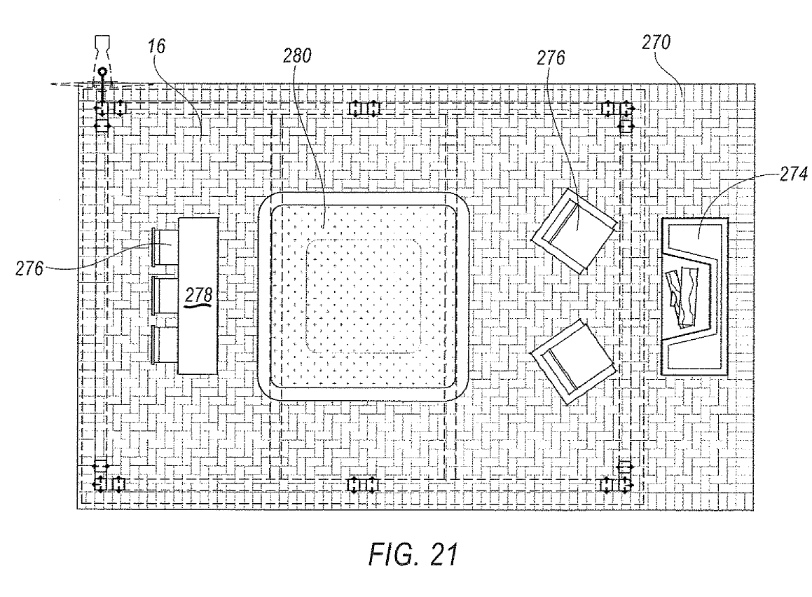

Alternatively, as shown in FIGS. 19-21, the activity space 16 may be outfitted for passive outdoor activities, such as preparing or serving food, and/or providing entertainment. For such purposes, an appropriate surface 270, such as concrete, patio blocks or brick may provided within the activity space 16 and/or adjacent to the activity space. In the example illustrated, an entertainment system, such the video system 272, shown in FIG. 19 or the fireplace 274, shown in FIGS. 20 and 21 are be provided. The activity space may further be provided with suitable seating 276 as well as suitable surfaces such as tables 278 for activities such as reading, writing, playing board or card games or serving and consuming food. As shown in FIG. 21, a large cushion or ottoman 280 may also be provided for sitting or reclining.

The activity space 16 may be open when outfitted for passive outdoor activities as shown in FIGS. 19-21 or may be partially or totally enclosed, as needed, by attaching to the columns 30 appropriate optical barrier panels, not shown, such as to reduce glare, to reduce entry of ultraviolet light, to block visibility of activities within the solar structure 10, or to block visibility from within the solar structure of less aesthetically pleasing vistas.

Still further types of activity devices may be supported by the solar structure. For example, the activity devices may be suitable modular platforms and work surfaces attachable directly to the columns 30 for repotting plants, for preparing or serving food, or for other outdoor activities. Alternatively, the solar structure 10 may be outfitted as a stage for outdoor entertainment at family events such as for deejaying, karaoke, live musicians, puppet shows, and grandchildren's recital performances or ad hoc skits. If needed, the electric power converter 110 may be used to provide power required to support the outdoor activity, such as power for cooking, cooling, and heating food and for amplifying entertainment sources.

The activity device may include a human operable bicycle or physical trainer device or an animal exercise device adapted to output power which may be aggregated with other sources of power by the electric power converter 110.

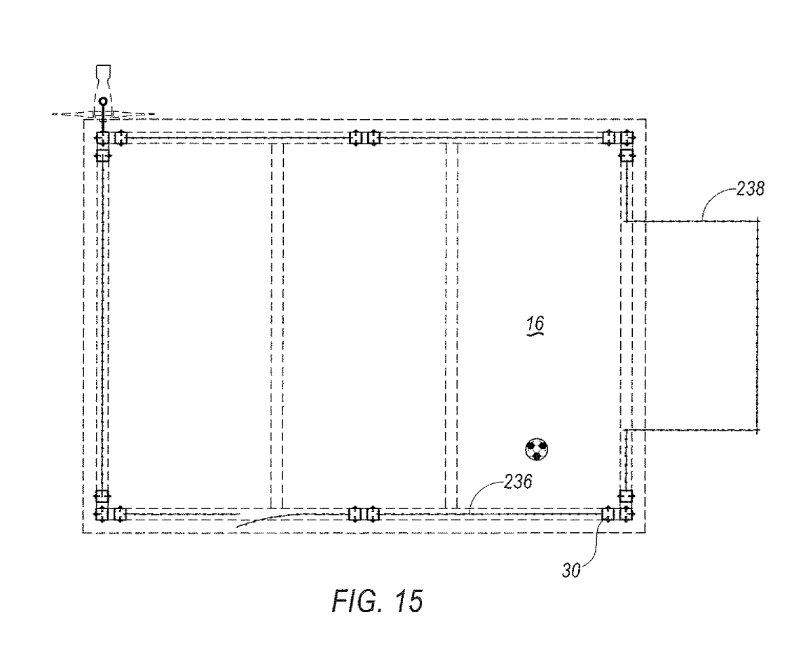

Furthermore, the various activity devices described above may be combined to better support outdoor activities or to support multiple activities. For example, one or two decorative panels 230 of the type illustrated in FIG. 13, each with appropriate openings for access to the climbing wall 204, tube 206 and slide 208, may be combined with the jungle gym of FIGS. 9 and 10 to define the entire space or to define platform 200 as a clubhouse. The netting 236 of the soccer arena of FIGS. 14 and 15 may be combined with the passive recreational system of FIGS. 19-21 to inhibit the entry of insects into the activity space 16.

It will therefore be appreciated that the solar structure increases the lifestyle value received by a homeowner on an investment in renewal energy devices by providing a dual purpose outdoor modular structure that provides for an outdoor activity center below a renewable power center. It further provides a homeowner with the option of receiving the benefits of using renewable power without modifying the roof of the house. In certain exemplary embodiments, it also provides the increased advantage of providing power when needed to support outdoor activities.

The present invention has been particularly shown and described with reference to the foregoing embodiments, which are merely illustrative of the best modes for carrying out the invention. It should be understood by those skilled in the art that various alternatives to the embodiments of the invention described herein may be employed in practicing the invention without departing from the spirit and scope of the invention as defined in the following claims. It is intended that the following claims define the scope of the invention and that the method and apparatus within the scope of these claims and their equivalents be covered thereby. This description of the invention should be understood to include all novel and non-obvious combinations of elements described herein, and claims may be presented in this or a later application to any novel and non-obvious combination of these elements. Moreover, the foregoing embodiments are illustrative, and no single feature or element is essential to all possible combinations that may be claimed in this or a later application.

What is claimed is:

1. A solar structure comprising:
a support structure comprising a frame and a plurality of columns capable of supporting the roof frame above the ground;
a plurality of solar panels capable of being supported by the frame in an orientation to receive sunlight; and
an activity device adapted to be supported by the support structure below the frame.

2. The solar structure of claim 1 further comprising a roof capable of being supported by the support structure below the frame in a position above the activity device.

3. The solar structure of claim 2 wherein the roof capable of being suspended from the frame.

4. The solar structure of claim 1 further comprising an electric power converter electrically connected to the plurality of solar panels to receive electric power from the plurality of solar panels in a first format and convert the power to a second power format.

5. The solar structure of claim 1 further comprising a second non-solar renewable electric power source.

6. The solar structure of claim 5 wherein the second non-solar renewable electric power source comprises a wind turbine.

7. The solar structure of claim 6 further comprising a mast capable of being supported by the support structure and extended upwardly therefrom, and further wherein the wind turbine is capable of being supported by the support structure.

8. The solar structure of claim 5 further comprising an electric power converter electrically connected to the plurality solar panels and the second non-solar renewable electric power source and adapted to receive electric power from the plurality of solar panels and the second non-solar renewable electric power source and convert the electric power from their original power formats to a predetermined output power format.

9. The solar structure of claim 1 wherein the activity device comprises a recreational device.

10. The solar structure of claim 9 wherein the recreational device is a human recreational device.

11. The solar structure of claim 9 wherein the recreational device comprises at least one component of a jungle gym.

12. The solar structure of claim 9 wherein the at least component of a jungle gym comprises at least one of a tube, a swinging device, a climbing device, a hanging device, and a sliding device.

13. The solar structure of claim 1 wherein the activity device comprises at least one of a platform, netting, a playhouse, an arena, a goal, a putting green, an animal agility device, a kennel, a food staging area, an entertainment center and an ice rink.

14. The solar structure of claim 1 wherein the frame comprises an outer frame supported by the columns and at least one cross member extending between portions of the outer frame.

15. The solar structure of claim 1 further wherein the recreational device is capable of being interconnected with at least one of the columns.

16. The solar structure of claim 1 further wherein the recreational device is disposed at least partially under the frame when mounted to the support structure.

17. The solar structure of claim 1 further wherein the activity comprises at least a partial barrier to shield the plurality of solar panels.

18. The solar structure of claim 1 wherein at least one of the plurality of solar panels is pivotably supported by the frame and pivotable to an orientation to receive sunlight.

19. The solar structure of claim 1 wherein the frame comprises a plurality of interconnected beams.

20. A solar structure comprising:
a support structure comprising a roof frame and a plurality of columns capable of supporting the roof frame above the ground;
a plurality of solar panels capable of being pivotably supported by the roof frame and pivotable to an orientation to receive sunlight; and
a power converter capable of being supported by the support structure and electrically connected to plurality of solar panels to receive electric power from the plurality of solar panels and convert the power from a first format to a second format.

21. The solar structure of claim 20 further comprising an activity device capable of being supported by the support structure at least partially below the roof frame.

22. The solar structure of claim 20 further comprising a roof capable of being suspended from the roof frame.

23. The solar structure of claim 20 further comprising a renewable non-solar electric power source.

24. The solar structure of claim 23 wherein the renewable non-solar electric power source comprises a wind turbine.

25. The solar structure of claim 20 wherein the at least one of the plurality of solar panels is pivotable upwardly and downwardly to facilitate desired orientation relative to sunlight.

26. The solar structure of claim 20 wherein the at least one of the plurality of solar panels is pivotable side to side to facilitate a desired orientation relative to sunlight.

27. A solar structure comprising:
a support structure comprising a roof frame and a plurality of columns capable of supporting the roof frame above the ground;
at least one solar panel capable of being supported by the support structure in an orientation to receive sunlight;
an activity device capable of being supported by the support structure below the roof frame;
a power converter capable of being supported by the support structure and electrically connected to plurality of solar panels to receive electric power from the plurality of solar panels and to convert the electric power from a first format to a second format; and
a power transmission system capable of connecting the electrical power converter to a power consumption system.

28. The solar structure of claim 27 wherein the activity device comprises at least one of a jungle gym, a platform, netting, a ladder, a tube, a swing, a slide, a jungle gym, a playhouse, an arena, a goal, a putting green, a kennel, an animal agility device, a food staging area, an entertainment center and an ice rink.

29. The solar structure of claim 27 further comprising a roof capable of being supported by the support structure below the roof frame and above the recreational device.

30. The solar structure of claim 27 further comprising a renewable non-solar electric power source.

31. The solar structure of claim 30 wherein the renewable non-solar electric power source comprises a wind turbine.

32. The solar structure of claim 27 wherein the at least one solar panel is pivotable to facilitate desired orientation relative to sunlight.
